(19) United States
(12) Patent Application Publication
(10) Pub. No.: US 2026/0223395 A1
(43) Pub. Date: Jul. 30, 2026

(54) SEMICONDUCTOR DEVICE

(71) Applicant: Panasonic Holdings Corporation, Osaka (JP)

(72) Inventors: Daisuke SHIBATA, Kyoto (JP); Satoshi TAMURA, Osaka (JP)

(21) Appl. No.: 19/532,187

(22) Filed: Feb. 6, 2026

Related U.S. Application Data
(63) Continuation of application No. PCT/JP2024/018317, filed on May 17, 2024.

(30) Foreign Application Priority Data
Aug. 24, 2023 (JP) 2023-136403

(51) Int. Cl. H10D 30/66; H10D 62/85

(52) U.S. Cl. CPC H10D 30/668; H10D 62/8503

(57) ABSTRACT

A semiconductor device includes a substrate, a first semiconductor layer of a first conductivity type disposed above the substrate, a second semiconductor layer of a second conductivity type that is disposed above the first semiconductor layer, a third semiconductor layer disposed to cover a first opening that penetrates through the second semiconductor layer, a gate electrode disposed above the third semiconductor layer to cover the first opening, a source electrode disposed apart from the gate electrode, and a drain electrode disposed below the substrate. The third semiconductor layer includes a first region having a substantially uniform thickness and a second region having a thickness smaller than the thickness of the first region outside the first opening in the planar view of the substrate, and both of the gate electrode and the source electrode do not overlap with the second region in the planar view of the substrate.

### CROSS REFERENCE TO RELATED APPLICATIONS

This is a continuation application of PCT International Application No. PCT/JP2024/018317 filed on May 17, 2024, designating the United States of America, which is based on and claims priority of Japanese Patent Application No. 2023-136403 filed on Aug. 24, 2023. The entire disclosures of the above-identified applications, including the specifications, drawings and claims are incorporated herein by reference in their entirety.

### FIELD

The present disclosure relates to a semiconductor device.

### BACKGROUND

Nitride semiconductors represented by GaN are wide-bandgap semiconductors with a large bandgap, and have features such as a large dielectric breakdown electric field and a saturated drift rate of electrons higher than those of compound semiconductors composed of GaAs or Si semiconductors. For example, the bandgap of GaN and that of AlN are 3.4 eV and 6.2 eV at room temperature, respectively. For this reason, research and development of power transistors including a nitride semiconductor that increases output and/or breakdown voltage have been actively conducted.

Patent Literature (PTL) 1 discloses a vertical field effect transistor (FET). PTL 1 discloses occurrence of anomaly growth of a regrowth layer when the regrowth layer is disposed to cover a gate opening. In PTL 1, such anomaly growth is suppressed by the gate opening having an outline which is at least partially along an arc or an elliptical arc.

### CITATION LIST

### Patent Literature

PTL 1: Japanese Patent No. 7017579

### SUMMARY

### Technical Problem

In the vertical field effect transistor disclosed in PTL 1, an increase in leakage current and a reduction in breakdown voltage are observed.

Thus, the present disclosure provides a semiconductor device having low leakage current and high breakdown voltage.

### Solution to Problem

The semiconductor device according to one aspect of the present disclosure includes a substrate; a first semiconductor layer of a first conductivity type disposed above the substrate; a second semiconductor layer of a second conductivity type disposed above the first semiconductor layer, the second conductivity having a polarity different from a polarity of the first conductivity type; a third semiconductor layer disposed to cover a first opening that penetrates through the second semiconductor layer and reaches the first semiconductor layer; a gate electrode disposed above the third semiconductor layer to cover the first opening; a source electrode disposed apart from the gate electrode; and a drain electrode disposed below the substrate. Here, in a planar view of the substrate, outside the first opening, the third semiconductor layer includes: a first region having a substantially uniform thickness; and a second region having a thickness smaller than the thickness of the first region, and in the planar view of the substrate, both of the gate electrode and the source electrode do not overlap with the second region.

### Advantageous Effects

The present disclosure can provide a semiconductor device having low leakage current and high breakdown voltage.

### BRIEF DESCRIPTION OF DRAWINGS

These and other advantages and features will become apparent from the following description thereof taken in conjunction with the accompanying Drawings, by way of non-limiting examples of embodiments disclosed herein.

FIG. 1 is a cross-sectional view of a semiconductor device according to Embodiment 1.

FIG. 2 is a plan view of the semiconductor device according to Embodiment 1.

FIG. 3 is a cross-sectional view schematically illustrating the off-angle of a substrate.

FIG. 4 is a plan view schematically illustrating the anomaly growth region of a regrowth layer.

FIG. 5 is a cross-sectional view schematically illustrating the anomaly growth region of a regrowth layer.

FIG. 6 is an enlarged plan view of the semiconductor device according to Embodiment 1.

FIG. 7 is a graph illustrating off properties of the semiconductor device according to Embodiment 1.

FIG. 8 is a plan view of a semiconductor device according to Embodiment 2.

FIG. 9 is an enlarged plan view of the semiconductor device according to Embodiment 2.

### DESCRIPTION OF EMBODIMENTS

### (Summary of the Present Disclosure)

The semiconductor device according to a first aspect of the present disclosure includes a substrate; a first semiconductor layer of a first conductivity type disposed above the substrate; a second semiconductor layer of a second conductivity type disposed above the first semiconductor layer, the second conductivity having a polarity different from a polarity of the first conductivity type; a third semiconductor layer disposed to cover a first opening that penetrates through the second semiconductor layer and reaches the first semiconductor layer; a gate electrode disposed above the third semiconductor layer to cover the first opening; a source electrode disposed apart from the gate electrode; and a drain electrode disposed below the substrate. Here, in a planar view of the substrate, outside the first opening, the third semiconductor layer includes: a first region having a substantially uniform thickness; and a second region having a thickness smaller than the thickness of the first region, and in the planar view of the substrate, both of the gate electrode and the source electrode do not overlap with the second region.

To be noted, “substantially uniform thickness (or film thickness)” means that, for example, when the thickness of the film as a subject is measured in several places within the target region, the difference between each of the measured values of the thickness and the average of the measured values is 10% or less of the average of the measured values. The number of places for measurement can be 2 or more and 10 or less. Alternatively, the case where the angle formed by the upper surface of the film and the lower surface thereof in a cross-section of the film cut in the thickness direction is 2° or less may be regarded as “substantially uniform thickness”.

The third semiconductor layer can be formed, for example, by a crystal regrowth step after the formation of the first opening. In the planar view of the substrate, the third semiconductor layer includes the second region as an anomaly growth region caused due to anomaly growth in the crystal regrowth step. The second region, which has a thickness larger than that of the first region, can increase the leakage current. For example, when the gate electrode or the source electrode is disposed to overlap with the second region in the planar view of the substrate, a leakage current is generated between the drain electrode disposed below the substrate and the gate electrode or the source electrode, and can lead to a reduction in breakdown voltage.

In contrast, the semiconductor device according to this aspect includes neither the gate electrode nor the source electrode in the second region in the planar view. Accordingly, an increase in leakage current can be suppressed, and high breakdown voltage properties can be implemented.

The semiconductor device according to a second aspect of the present disclosure is the semiconductor device according to the first aspect, in which the third semiconductor layer includes: a fourth semiconductor layer including a channel region; and a fifth semiconductor layer of the second conductivity type disposed between the fourth semiconductor layer and the gate electrode.

Thereby, the fifth semiconductor layer of the second conductivity type can raise the potential of the channel, and thus the semiconductor device can be operated with normally off properties.

The semiconductor device according to a third aspect of the present disclosure is the semiconductor device according to the second aspect, in which the source electrode has a shape elongated in a first direction in the planar view of the substrate, and in the planar view of the substrate, the first opening includes: two straight line portions that sandwich the source electrode and extend in the first direction; a first connection portion of an arch shape that connects first ends of the two straight line portions in the first direction; and a second connection portion of an arch shape that connects second ends of the two straight line portions on a side opposite to the first ends.

Thereby, the first connection portion and the second connection portion can have a reduced curvature, and generation of growth singular points can be significantly suppressed. For this reason, an increase in leakage current via growth singular points can be suppressed, and high breakdown voltage properties can be implemented.

To be noted, the growth singular points are positions from which anomaly growth generates, and specifically correspond to bending points of the outline of the opening. As the two line segments at the bending point form a larger angle, anomaly growth is less likely to generate. For this reason, by connecting the ends of the straight line portions into an arch shape, for example, the outline of the opening can have a smoothly curved shape like an arc, thus suppressing anomaly growth.

The semiconductor device according to a fourth aspect of the present disclosure is the semiconductor device according to the third aspect, in which three or more source electrodes are included, each of which is the source electrode, two or more first openings are aligned in a second direction orthogonal to the first direction, each of which is the first opening, the three or more source electrodes are aligned in the second direction, and each of the three or more source electrodes is disposed between adjacent first openings among the two or more first openings.

Thereby, the current, that is, the output can be increased. In addition, the first connection portion and the second connection portion can be configured not to be arranged in the first direction for the source electrode disposed between adjacent first openings. For this reason, the anomaly growth region attributed to the first connection portion and the second connection portion can be reduced, and thus, the leakage current can be further reduced and higher breakdown voltage properties can be implemented.

The semiconductor device according to a fifth aspect of the present disclosure is the semiconductor device according to the second aspect, in which a plurality of source electrodes are included, each of which is the source electrode, the plurality of source electrodes each have a shape elongated in a first direction in the planar view of the substrate, in the planar view of the substrate, the plurality of source electrodes are aligned in a second direction orthogonal to the first direction, and in the planar view of the substrate, the first opening includes: a plurality of straight line portions, each of which is disposed between adjacent source electrodes in the second direction among the plurality of source electrodes and extends in the first direction; a first connection portion including portions of an arch shape that are continuously arranged in the second direction and each connect first ends of the plurality of straight line portions in the first direction; and a second connection portion including portions of an arch shape that are continuously arranged in the second direction and each connect second ends of the plurality of straight line portions on a side opposite to the first ends.

Thereby, the first connection portion and the second connection portion can have a reduced curvature, and generation of growth singular points can be significantly suppressed. For this reason, an increase in leakage current via growth singular points can be suppressed, and high breakdown voltage properties can be implemented.

The semiconductor device according to a sixth aspect of the present disclosure is the semiconductor device according to any one of the third to fifth aspects, in which a plurality of source electrodes aligned in the first direction are included, each of which is the source electrode, and each of a plurality of straight line portions continuously extends across the plurality of source electrodes aligned in the first direction.

Thereby, the current can be further increased, that is, higher output properties can be implemented.

The semiconductor device according to a seventh aspect of the present disclosure is the semiconductor device according to any one of the third to sixth aspects, in which when in the planar view of the substrate, a virtual straight line that passes through a center of the source electrode and is parallel to the first direction is defined as a first virtual straight line, and a virtual straight line that passes through a center of the source electrode and is orthogonal to the first direction is defined as a second virtual straight line, (a) a distance on the second virtual straight line between an outline of one of the two straight line portions on a side of the source electrode and an outline of the fifth semiconductor layer on the side of the source electrode is defined as a first distance, (b) a distance on the first virtual straight line between an outer edge outline of the fifth semiconductor layer on a side of the first connection portion and an outline of the first connection portion on a side opposite to the source electrode is defined as a second distance, and (c) a distance on the first virtual straight line between an outline of the second connection portion on the side of the source electrode and an outline of the fifth semiconductor layer located between the source electrode and the second connection portion on the side of the source electrode is defined as a third distance, both of the second distance and the third distance are longer than the first distance.

When the third semiconductor layer is formed by the crystal regrowth step to cover the first opening, the anomaly growth region shed along the off-angle direction of the substrate is likely to be generated. In addition, to implement a favorable transistor operation in the semiconductor device, the gate electrode that surrounds the source electrode and is disposed close thereto is desirably a normal gate electrode without anomaly growth. For this reason, to avoid the anomaly growth region, by making the second distance and the third distance longer than the first distance in the end of the source electrode in the longitudinal direction (that is, first direction), an increase in leakage current via the anomaly growth region can be suppressed, and high breakdown voltage properties can be implemented.

The semiconductor device according to an eighth aspect of the present disclosure is the semiconductor device according to the seventh aspect, in which when in the planar view of the substrate, (a) a distance on the first virtual straight line between an outline of the first connection portion on the side of the source electrode and an outline of the fifth semiconductor layer located between the source electrode and the first connection portion on the side of the source electrode is defined as a fourth distance, and (b) a distance on the first virtual straight line between an outer edge outline of the fifth semiconductor layer on a side of the second connection portion and an outline of the second connection portion on a side opposite to the source electrode is defined as a fifth distance, both of the fourth distance and the fifth distance are longer than the first distance.

Thereby, irrespective of whether the off-direction of the substrate is one of the positive side and the negative side of the first direction, a normal gate electrode without any anomaly growth region can be disposed. For this reason, an increase in leakage current via the anomaly growth region can be suppressed, and high breakdown voltage properties can be implemented.

The semiconductor device according to a ninth aspect of the present disclosure is the semiconductor device according to any one of the first to eighth aspects, in which a second opening that penetrates through the third semiconductor layer and reaches the second semiconductor layer is disposed in a position apart from the first opening in the planar view of the substrate, and at least part of the source electrode is disposed inside the second opening.

Thereby, the second semiconductor layer can be in contact with the source electrode inside the second opening, and thus, the potential of the second semiconductor layer can be fixed to the source potential. For this reason, the operation stability of the transistor and the breakdown voltage can be increased. Moreover, the source electrode can be in contact with the channel inside the second opening, and thus the source contact resistance can also be reduced.

The semiconductor device according to a tenth aspect of the present disclosure is the semiconductor device according to any one of the first to ninth aspects, in which the source electrode has a shape elongated in a first direction in the planar view of the substrate, and the substrate includes an upper surface having an off-angle inclined with respect to the first direction.

This can prevent generation of the anomaly growth region in the lateral direction of the first opening that may affect the operation of the device, and thus can suppress a reduction in properties of the semiconductor device.

The semiconductor device according to an eleventh aspect of the present disclosure is the semiconductor device according to the tenth aspect, in which the substrate contains gallium nitride, and the first direction is an a-axis direction of gallium nitride.

Thereby, it is more likely to reduce the ohmic contact resistance of the source electrode. Accordingly, the on-resistance can be reduced.

The semiconductor device according to a twelfth aspect of the present disclosure is the semiconductor device according to the tenth aspect, in which the substrate contains gallium nitride, and the first direction is an m-axis direction of gallium nitride.

Thereby, the semiconductor layer formed on the substrate by crystal growth can have a surface with favorable flatness. This leads to increased stability of processes such as light exposure, which can provide a semiconductor device with high quality and improve the yield.

The semiconductor device according to a thirteenth aspect of the present disclosure is the semiconductor device according to any one of the first to twelfth aspects, in which the first semiconductor layer, the second semiconductor layer, and the third semiconductor layer all contain a nitride semiconductor as a main component.

Thereby, a high output and a high breakdown voltage can be implemented by using a nitride semiconductor having a large bandgap.

Hereinafter, embodiments will be specifically described with reference to the drawings.

The embodiments described below all illustrate general or specific examples. Numeric values, shapes, materials, components, arrangement positions of components and connection forms thereof, and the like shown in embodiments below are exemplary, and are not construed as limitations to the present disclosure. Moreover, among the components of the embodiments below, the components not described in an independent claim will be described as optional components.

The drawings are schematic views, and are not necessarily precise illustrations. Accordingly, for example, the scale is not always consistent among the drawings. In the drawings, identical reference signs are given to substantially identical configurations, and duplication of description will be omitted or simplified.

In this specification, terms representing relations between entities, such as parallel or orthogonal, terms representing shapes of entities, such as circle or ellipse, and numeric value ranges are not expressions representing only their strict meanings, but expressions including substantially equal ranges, such as a difference of about several percentage.

In this specification and the drawings, the x-axis, the y-axis, and the z-axis indicate three axes in a three-dimensional orthogonal coordinate system. When the substrate has a rectangular shape in the planar view of the substrate, the x-axis and the y-axis are a first side of the rectangular shape and a direction parallel to a second side orthogonal to the first side, respectively. The z-axis is the thickness direction of the substrate. In this specification, the “thickness direction” of the substrate refers to the direction vertical to the main surface of the substrate. The thickness direction is the same as the stacking direction of the semiconductor layers, and is also referred to as “longitudinal direction”. The direction parallel to the main surface of the substrate may be referred to as “traverse direction” in some cases.

The side of the substrate on which the gate electrode and the source electrode are arranged is regarded as “above” or “upper side”, and the side of the substrate on which the drain electrode is disposed is regarded as “below” or “lower side”.

In this specification, the terms “above” and “below” do not indicate an upper direction (upper in the vertical direction) and a lower direction (lower in the vertical direction) in absolute spatial recognition, but are used as terms specified by relative positional relation based on the stacking order of the stacking configuration. The terms “above” and “below” are used not only when two components are arranged with an interval and another component is present between the two components, but also when two components are disposed in close contact with each other.

In this specification, unless otherwise specified, the expression “in the planar view” indicates viewing of the nitride semiconductor device in a direction vertical to the main surface of the substrate, that is, viewing of the main surface of the substrate from the front side.

In this specification, the expression “distance between A and B in the planar view” indicates the shortest distance between A and B in the planar view. When A and B have predetermined sizes, in the planar view, among countless line segments connecting any point on the outline representing the contour of A and any point on the outline representing the contour of B, the length of the shortest line segment is the distance.

In this specification, unless otherwise specified, ordinals such as “first” and “second” do not mean the number or order of components, but are used to avoid confusion of components of similar types and distinguish these.

In this specification, AlGaN represents a tertiary mixed crystal AlₓGa₁₋ₓN (where 0<x<1). Hereinafter, multicomponent mixed crystals are abbreviated based on arrangement of constitutional element symbols, such as AlInN and GaInN, for example. For example, AlₓGa_{1-x-y}In_{y}N (where 0<x<1, 0<y<1, and 0<x+y<1) as one example of the nitride semiconductor is abbreviated to AlGaInN.

### Embodiment 1

### [Configuration]

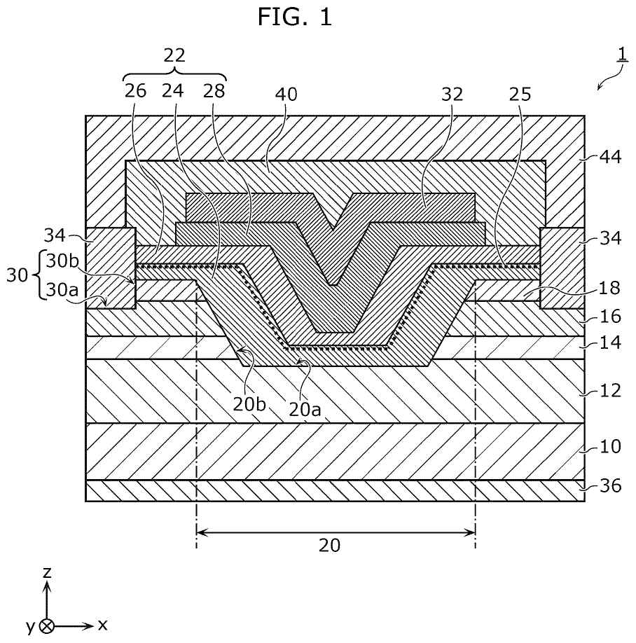

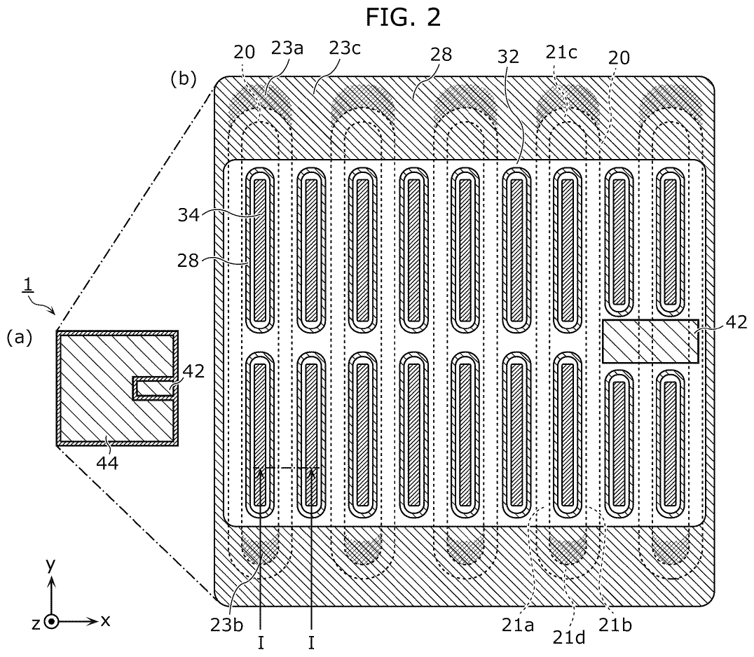

First, the configuration of the semiconductor device according to Embodiment 1 will be described with reference to FIGS. 1 and 2.

FIG. 1 is a cross-sectional view of semiconductor device 1 according to the present embodiment. In FIG. 1, the components such as semiconductor layers and electrodes are hatched to indicate a cross-section. FIG. 1 illustrates a cross-section taken along line I-I in FIG. 2.

FIG. 2 is a plan view of semiconductor device 1 according to the present embodiment. (b) of FIG. 2 is an enlarged diagram of (a) of FIG. 2, in which illustration of source electrode pad 44 is omitted.

As illustrated in FIG. 1, semiconductor device 1 according to the present embodiment is a so-called vertical field effect transistor (FET). Specifically, in semiconductor device 1, a current flows between drain electrode 36 and source electrode 34 in a direction vertical to the main surface of substrate 10.

Semiconductor device 1 is a device having a stacking structure of nitride semiconductor layers containing nitride semiconductors such as GaN and AlGaN as main components. To be noted, “A contains B as a main component” means that the content of B in A is 50% or higher.

Semiconductor device 1 has a hetero structure composed of an AlGaN film and a GaN film. In the hetero structure composed of the AlGaN film and the GaN film, due to spontaneous polarization or piezoelectric polarization on a C plane represented by a (0001) plane, two-dimensional electron gas (2DEG) 25 generates in a high concentration at the hetero-interface. For this reason, without doping, sheet carrier concentration of 1×10¹³ cm⁻² or higher is obtained at the interface.

Semiconductor device 1 according to the present embodiment is a normally-off FET. In semiconductor device 1, for example, source electrode 34 is grounded (namely, the potential is 0 V), and a positive potential is given to drain electrode 36. The potential given to drain electrode 36 is 100 V or more and 1200 V or less, for example, but not limited thereto. When semiconductor device 1 is in an off state, 0 V or a negative potential (for example, −5 V) is applied to gate electrode 32. When semiconductor device 1 is in an on state, a positive potential (for example, +5 V) is applied to gate electrode 32. To be noted, semiconductor device 1 may be a normally-on FET.

As illustrated in FIGS. 1 and 2, semiconductor device 1 includes substrate 10, drift layer 12, first underlying layer 14, second underlying layer 16, third underlying layer 18, regrowth layer 22, gate electrode 32, source electrode 34, drain electrode 36, interlayer insulating film 40, gate electrode pad 42, and source electrode pad 44. In semiconductor device 1, gate opening 20 and source opening 30 are arranged. In FIG. 2, the outline of gate opening 20 in the planar view is represented by the dashed lines. The outline of gate opening 20 corresponds to the upper ends of lateral surface 20b of gate opening 20. The specific planar layout will be described later. Hereinafter, first, a cross-sectional configuration of semiconductor device 1 will be mainly described.

Substrate 10 contains a nitride semiconductor. Specifically, substrate 10 contains gallium nitride (GaN). The shape of substrate 10 in the planar view is a rectangular shape, for example, although it is not limited thereto.

Substrate 10 is, for example, an n⁺-type GaN substrate with a thickness of 300 μm and a carrier concentration of 1×10¹⁸ cm⁻³. The n-type and the p-type each indicate a conductivity type of a semiconductor. The n⁺-type indicates a state where a high concentration of an n-type dopant is added to the semiconductor, or the semiconductor is heavily doped with the n-type dopant. The n⁻-type indicates a state where a low concentration of an n-type dopant is added to the semiconductor, or the semiconductor is lightly doped with the n-type dopant. The n-type, the n⁺-type, and the n-type are all examples of a first conductivity type, and may be collectively referred to as n-type. The p-type, the p⁺-type, and the p-type are all examples of a second conductivity type having a polarity different from that of the first conductivity type, and may be collectively referred to as p-type.

Substrate 10 includes an upper surface having an off-angle inclined with respect to a y-axis direction. The y-axis direction is one example of the first direction, and means the positive direction of the y-axis, the negative direction thereof, or both of the directions.

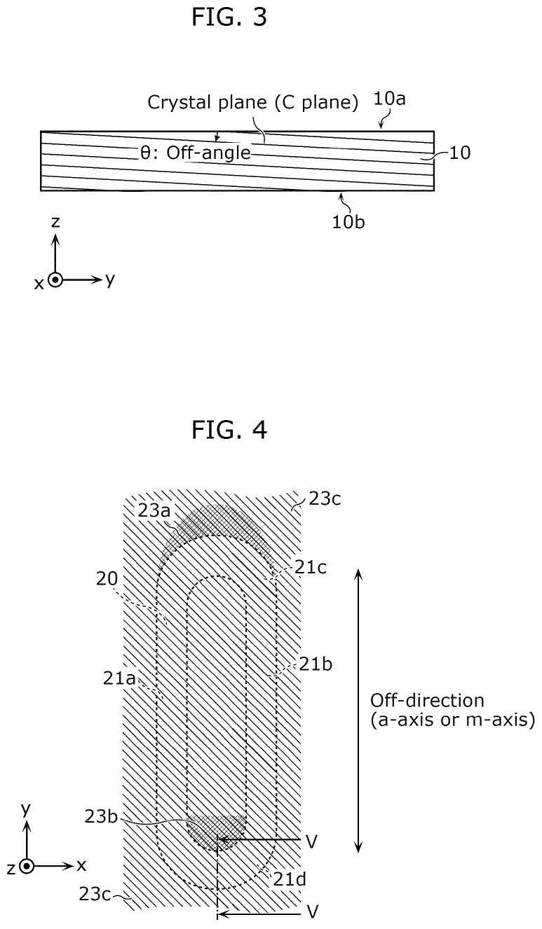

FIG. 3 is a cross-sectional view schematically illustrating off-angle θ of substrate 10. In FIG. 3, a crystal plane of GaN is represented by oblique lines in substrate 10. Off-angle θ can be shown as an angle formed by the crystal plane of GaN and upper surface 10a or lower surface 10b of substrate 10. Off-angle θ is more than 0° and 5° or less, for example. Off-angle θ may be 0.1° or more. Off-angle θ may be 1° or less, or may be 0.5° or less. Top surface 10a and lower surface 10b are each the main surface of substrate 10.

The crystal structure of GaN crystals can be expressed by three directions, i.e., a-axis direction, m-axis direction, and c-axis direction. The a-axis direction is the [11-20] direction. The m-axis direction is the [1-100] direction. The c-axis direction is the [0001] direction. The crystal plane of GaN illustrated in FIG. 3 is the C plane, and is also called as (0001) plane. The inclined direction of the crystal plane is called off-direction, and is the a-axis direction or the m-axis direction, for example.

To be noted, substrate 10 need not be a nitride semiconductor substrate. For example, substrate 10 may be a silicon (Si) substrate, a silicon carbide (SiC) substrate, or a zinc oxide (ZnO) substrate.

Drift layer 12 is one example of the first semiconductor layer of the first conductivity type disposed above substrate 10. Drift layer 12 contains a nitride semiconductor as the main component. Drift layer 12 is an n-type GaN film with a thickness of 8 μm, for example. The donor concentration in drift layer 12 is, for example, 1×10¹⁵ cm⁻³ or higher and 1×10¹⁷ cm⁻³ or lower, and is 1×10¹⁶ cm⁻³ as one example. The carbon concentration (C concentration) of drift layer 12 is 1×10¹⁵ cm⁻³ or higher and 2×10¹⁷ cm⁻³ or lower, for example.

For example, drift layer 12 is disposed in contact with upper surface (main surface) 10a of substrate 10. For example, drift layer 12 is formed on upper surface 10a of substrate 10 by crystal growth such as metal organic vapor phase epitaxy (MOVPE) or hybrid vapor deposition (HVPE).

First underlying layer 14 is one example of the nitride semiconductor layer disposed above drift layer 12. In the present embodiment, first underlying layer 14 is disposed between drift layer 12 and second underlying layer 16. First underlying layer 14 is a high-resistance layer having a resistance higher than that of second underlying layer 16. For example, first underlying layer 14 is a GaN film with a thickness of 200 nm doped with carbon (C). First underlying layer 14 is disposed in contact with the upper surface of drift layer 12. First underlying layer 14 is formed on drift layer 12 by crystal growth such as MOVPE or HVPE, for example.

For example, the carbon concentration in first underlying layer 14 is 3×10¹⁷ cm⁻³ or higher, and may be 1×10¹⁸ cm⁻³ or higher. At this time, the concentration of silicon (Si) or oxygen (O) as an n-type impurity is lower than the carbon concentration. For example, the silicon concentration or oxygen concentration in first underlying layer 14 is 5×10¹⁶ cm⁻³ or lower, and may be 2×10¹⁶ cm⁻³ or lower. The same effects as those described above can also be provided by any other ion species than the above-mentioned ion species injected to first underlying layer 14 as long as these ion species can increase the resistance of the semiconductor layer.

Second underlying layer 16 is disposed above drift layer 12, and is one example of the second semiconductor layer of the second conductivity type. Second underlying layer 16 contains a nitride semiconductor as the main component. For example, second underlying layer 16 is a p-type GaN film with a thickness of 400 nm and a carrier concentration of 1×10¹⁷ cm⁻³. Second underlying layer 16 is disposed in contact with the upper surface of first underlying layer 14. For example, second underlying layer 16 is formed on first underlying layer 14 by crystal growth such as MOVPE or HVPE, for example.

Although second underlying layer 16 is formed by crystal growth, second underlying layer 16 may be formed by injecting magnesium (Mg) to the obtained i-GaN film, for example. Additionally, second underlying layer 16 may be an insulating layer obtained by injecting iron (Fe) or boron (B), but not a p-type nitride semiconductor layer.

Second underlying layer 16 suppresses a leakage current between source electrode 34 and drain electrode 36. For example, when a reverse voltage is applied to a pn junction formed by second underlying layer 16 and drift layer 12, specifically, when the potential of drain electrode 36 is higher than that of source electrode 34, a depletion layer extends to drift layer 12. Thereby, the breakdown voltage of semiconductor device 1 can be increased. In the present embodiment, the potential of drain electrode 36 is higher than that of source electrode 34 in both of the off state and the on state excluding the reverse conducting operation. For this reason, the breakdown voltage of semiconductor device 1 is increased.

In the present embodiment, as illustrated in FIG. 1, second underlying layer 16 is in contact with source electrode 34. For this reason, second underlying layer 16 is fixed to the source potential applied to source electrode 34. Thereby, the potential of second underlying layer 16 is stabilized, and thus effects such as stabilization of operation of the transistor and an improvement in breakdown voltage can be obtained.

Third underlying layer 18 is one example of the semiconductor layer disposed above second underlying layer 16. Third underlying layer 18 is a high-resistance layer having a resistance higher than that of second underlying layer 16. For example, third underlying layer 18 is a GaN (i-GaN) film with a thickness of 200 nm. Third underlying layer 18 is disposed in contact with the upper surface of second underlying layer 16. Third underlying layer 18 is formed on second underlying layer 16 by crystal growth such as MOVPE or HVPE, for example.

Third underlying layer 18 is an undoped semiconductor layer, and may be an insulating layer or a semi-insulating layer. Here, “undoped” means that the layer is not doped with a dopant for changing the polarity of GaN to the n-type or the p-type, such as Si or Mg. For example, third underlying layer 18 may be doped with carbon (C) as in first underlying layer 14. For example, the carbon concentration in third underlying layer 18 is higher than the carbon concentration in second underlying layer 16.

For example, the carbon concentration of third underlying layer 18 is 3×10¹⁷ cm⁻³ or higher, and may be 1×10¹⁸ cm⁻³ or higher. At this time, the concentration of silicon (Si) or oxygen (O) as an n-type impurity is lower than the carbon concentration. For example, the silicon concentration or oxygen concentration in third underlying layer 18 is 5×10¹⁶ cm⁻³ or lower, and may be 2×10¹⁶ cm⁻³ or lower. The same effects as those described above can also be provided by any other ion species than the above-mentioned ion species injected to third underlying layer 18 as long as these ion species can increase the resistance of the semiconductor layer.

To be noted, the upper surface of third underlying layer 18 may include a layer for suppressing diffusion of a p-type impurity such as Mg from second underlying layer 16. For example, an AlGaN layer with a thickness of 20 nm as a diffusion suppression layer may be disposed between the upper surface of third underlying layer 18 and regrowth layer 22. For example, an InAlGaN layer can also be used as a diffusion suppression layer. When Mg diffuses to the vicinity of the channel, the carrier concentration of two-dimensional electron gas 25 reduces and the on-resistance increases. Formation of the diffusion suppression layer can suppress an increase in on-resistance. To be noted, because the degree of diffusion of Mg is varied according to crystal growth conditions, the diffusion suppression layer is not always needed. Moreover, at least one of first underlying layer 14 and third underlying layer 18 does not need to be disposed.

In semiconductor device 1, drift layer 12, first underlying layer 14, second underlying layer 16, and third underlying layer 18 are continuously formed on upper surface 10a of substrate 10 (see FIG. 3) by the crystal growth process. Semiconductor films corresponding to the respective layers are formed through crystal growth, and are partially removed by patterning to form gate opening 20. Specifically, gate opening 20 is formed by removing part of third underlying layer 18, part of second underlying layer 16, and part of first underlying layer 14 to partially expose drift layer 12. At this time, by removing a surface layer portion of drift layer 12 by a predetermined thickness (e.g., 300 nm), bottom surface 20a of gate opening 20 is formed lower than the lower surface of first underlying layer 14.

As a method of removing third underlying layer 18, second underlying layer 16, and first underlying layer 14, dry etching such as inductively coupled plasma etching (ICP) is used, and a chlorine-based gas is used as a process gas.

Gate opening 20 is one example of the first opening that penetrates through second underlying layer 16 and reaches drift layer 12. Specifically, gate opening 20 penetrates through third underlying layer 18, second underlying layer 16, and first underlying layer 14 in this order. Lower surface 20a of gate opening 20 is part of the upper surface of drift layer 12. As illustrated in FIG. 1, bottom surface 20a is located lower than in a position lower than the lower surface of first underlying layer 14. The lower surface of first underlying layer 14 corresponds to the interface between first underlying layer 14 and drift layer 12. Bottom surface 20a is parallel to the main surface of substrate 10, for example. When semiconductor device 1 is on, the drain current flows between drain electrode 36 and source electrode 34 through bottom surface 20a of gate opening 20.

In the present embodiment, gate opening 20 is formed to have an opening area that becomes larger as it is farther away from substrate 10. Specifically, lateral surface 20b of gate opening 20 is inclined. As illustrated in FIG. 1, the shape of gate opening 20 in a cross-sectional view is inverted trapezoidal, more specifically, inverted isosceles trapezoidal.

The tilt angle of lateral surface 20b to bottom surface 20a is, for example, 20° or more and 80° or less, and may be 30° or more and 45° or less. As the tilt angle is smaller, lateral surface 20b is closer to the C plane. Thus, the film quality of regrowth layer 22 formed along lateral surface 20b by crystal regrowth can be enhanced. On the other hand, as the tilt angle is larger, formation of excessively large gate opening 20 is more suppressed, and thus the size of semiconductor device 1 is reduced.

Regrowth layer 22 is one example of the third semiconductor layer disposed to cover gate opening 20. Regrowth layer 22 contains a nitride semiconductor as the main component. As illustrated in FIG. 1, regrowth layer 22 includes electron transport layer 24, electron supply layer 26, and threshold adjustment layer 28.

Electron transport layer 24 is one example of the first regrowth layer disposed to cover the upper surface of third underlying layer 18 and lateral surface 20b and bottom surface 20a of gate opening 20. Specifically, part of electron transport layer 24 is disposed along bottom surface 20a and lateral surface 20b of gate opening 20, and the remaining part of electron transport layer 24 is disposed on the upper surface of third underlying layer 18. For example, electron transport layer 24 is an undoped GaN film with a thickness of 150 nm. Although it is assumed that electron transport layer 24 is undoped, electron transport layer 24 may be partially changed to an n-type by Si-doping.

Electron transport layer 24 is in contact with drift layer 12 in bottom surface 20a and lateral surface 20b of gate opening 20. Electron transport layer 24 is in contact with first underlying layer 14, second underlying layer 16, and third underlying layer 18 in lateral surface 20b of gate opening 20. Furthermore, electron transport layer 24 is in contact with the upper surface of third underlying layer 18.

Electron transport layer 24 is one example of the fourth semiconductor layer including a channel region. Specifically, two-dimensional electron gas 25 as a channel generates near the interface between electron transport layer 24 and electron supply layer 26. In FIG. 1, two-dimensional electron gas 25 is schematically illustrated with the dotted line. Two-dimensional electron gas 25 is bent along the interface between electron transport layer 24 and electron supply layer 26, namely, along the inner surface of gate opening 20.

Although not illustrated in FIG. 1, an AlN layer with a thickness of about 1 nm is disposed as a second regrowth layer between electron transport layer 24 and electron supply layer 26. Thereby, alloy scattering can be suppressed to improve channel mobility and reduce the on-resistance. The AlN layer is not always needed.

Electron supply layer 26 is one example of the third regrowth layer disposed to cover the upper surface of second underlying layer 16 and lateral surface 20b and bottom surface 20a of gate opening 20. Electron transport layer 24 and electron supply layer 26 are arranged in this order from substrate 10 side. For example, electron supply layer 26 is an undoped AlGaN film with a thickness of 20 nm. Electron supply layer 26 is formed into a shape with a substantially uniform thickness along the upper surface of electron transport layer 24.

Electron supply layer 26 has a bandgap larger than that of electron transport layer 24. For this reason, an AlGaN/GaN hetero-interface is formed between electron supply layer 26 and electron transport layer 24. Electron supply layer 26 feeds electrons to the channel region formed in electron transport layer 24 (two-dimensional electron gas 25).

Threshold adjustment layer 28 is one example of the fifth semiconductor layer of the second conductivity type disposed between electron transport layer 24 and gate electrode 32. Specifically, threshold adjustment layer 28 is disposed between electron supply layer 26 and gate electrode 32, and is in contact with the upper surface of electron supply layer 26. For example, threshold adjustment layer 28 is a p-type AlGaN film with a thickness of 100 nm and a carrier concentration of 1×10¹⁷ cm⁻³.

Since threshold adjustment layer 28 is disposed, the potential of the channel portion is raised. For this reason, the threshold of the transistor can be increased, and a normally-off transistor can be implemented.

To be noted, gate electrode 32 may be disposed in contact with electron supply layer 26 without threshold adjustment layer 28. Alternatively, for example, instead of threshold adjustment layer 28, an insulating layer composed of SiN or SiO₂ may be disposed between gate electrode 32 and electron supply layer 26. Thereby, the gate current can be suppressed, and the threshold can be shifted to a positive direction to implement a normally-off operation.

Electron transport layer 24, electron supply layer 26, and threshold adjustment layer 28 are formed by forming gate opening 20, and then continuously forming nitride semiconductor films through a crystal regrowth step, followed by patterning in a predetermined shape. Specifically, an undoped GaN film as the base for electron transport layer 24, an undoped AlGaN film as the base for electron supply layer 26, and a p-type AlGaN film as the base for threshold adjustment layer 28 are continuously formed by MOVPE or HVPE. After the film formation, by removing part of the p-type AlGaN film by etching until the undoped AlGaN film is exposed, threshold adjustment layer 28 is formed. Furthermore, part of the undoped AlGaN film, part of the undoped GaN film, and part of third underlying layer 18 are continuously removed by etching until second underlying layer 16 is exposed. Thereby, source opening 30 that reaches second underlying layer 16 is formed, and electron supply layer 26 and electron transport layer 24 patterned in a predetermined shape are formed.

Source opening 30 is one example of the second opening that penetrates through regrowth layer 22 and reaches second underlying layer 16, the second opening being disposed in a position apart from gate opening 20 in the planar view of substrate 10. In the present embodiment, source opening 30 is disposed in a position apart from both of gate electrode 32 and threshold adjustment layer 28 in the planar view of substrate 10.

Lower surface 30a of source opening 30 is part of the upper surface of second underlying layer 16. As illustrated in FIG. 1, bottom surface 30a is located in a position lower than the interface between third underlying layer 18 and second underlying layer 16. Specifically, source opening 30 is formed by removing a surface layer portion of second underlying layer 16. Alternatively, bottom surface 30a may be flush with the interface between third underlying layer 18 and second underlying layer 16. For example, bottom surface 30a is parallel to the main surface of substrate 10.

As illustrated in FIG. 1, source opening 30 is formed with a predetermined opening area irrespective of the distance from substrate 10. Specifically, lateral surface 30b of source opening 30 is vertical to bottom surface 30a. In other words, the cross-sectional shape of source opening 30 is a rectangular shape.

Alternatively, source opening 30 may be formed with an opening area that becomes larger as it is farther away from substrate 10. Specifically, lateral surface 30b of source opening 30 may be inclined. For example, the cross-sectional shape of source opening 30 may be inverted trapezoidal, more specifically, inverted isosceles trapezoidal. At this time, the tilt angle of lateral surface 30b to bottom surface 30a may be within the range of 30° or more and 60° or less, for example. Such an inclination of lateral surface 30b increases the contact area between source electrode 34 and electron transport layer 24 (two-dimensional electron gas 25), which facilitates formation of ohmic contact. To be noted, two-dimensional electron gas 25 is exposed to lateral surface 30b of source opening 30, and its exposed portion is connected to source electrode 34.

Source opening 30 is not always needed. Since source opening 30 is disposed, the ohmic contact resistance between two-dimensional electron gas 25 functioning as a channel and source electrode 34 can be reduced. Since second underlying layer 16 can be electrically connected to source electrode 34, the potential of second underlying layer 16 can be stabilized and the effects of stabilizing the operation of the transistor and improving the breakdown voltage can be obtained.

Gate electrode 32 is disposed above regrowth layer 22 to cover gate opening 20. Specifically, gate electrode 32 is disposed in contact with the upper surface of threshold adjustment layer 28.

Gate electrode 32 is formed using a conductive material such as a metal, for example. For example, for gate electrode 32, a material to be in ohmic contact with a p-type GaN layer can be used. For example, palladium (Pd), a nickel (Ni)-based material, tungsten silicide (WSi), or gold (Au) can be used.

Gate electrode 32 is formed by forming threshold adjustment layer 28, then forming source opening 30 or source electrode 34, and then forming a conductive film by sputtering or deposition, followed by patterning of the obtained conductive film.

Source electrode 34 is disposed in a position apart from gate electrode 32. In the present embodiment, at least part of source electrode 34 is disposed inside source opening 30. Specifically, source electrode 34 is disposed in contact with bottom surface 30a and lateral surface 30b of source opening 30 to fill in source opening 30. Source electrode 34 is in direct contact with two-dimensional electron gas 25 on lateral surface 30b of source opening 30. Thereby, the contact resistance between source electrode 34 and two-dimensional electron gas 25 can be reduced. Part of source electrode 34 may be disposed above the upper surface of electron supply layer 26.

Source electrode 34 is formed using a conductive material such as a metal. As the material for source electrode 34, for example, a material subjected to a heat treatment to form an ohmic contact with an n-type GaN layer, such as Ti/Al (stacking structure of a Ti layer and an Al layer), can be used. Source electrode 34 is formed, for example, by forming a conductive film by sputtering or deposition and patterning the obtained conductive film.

To be noted, source electrode 34 forms Schottky contact with p-type GaN. For this reason, to obtain a better contact between source electrode 34 and second underlying layer 16 containing p-type GaN as the main component, a metal material having a large work function that provides a lower contact resistance to p-type GaN such as Pd or Ni may be interposed therebetween. Thereby, the potential of second underlying layer 16 can be further stabilized.

Drain electrode 36 is disposed below substrate 10. Specifically, drain electrode 36 is disposed in contact with lower surface 10b of substrate 10.

Drain electrode 36 is formed using a conductive material such as a metal. As the material for drain electrode 36, for example, a material forming an ohmic contact with n-type GaN, such as Ti/Al, can be used. Drain electrode 36 is formed by sputtering or deposition, for example.

Interlayer insulating film 40 is disposed to electrically insulate gate electrode 32 and threshold adjustment layer 28 from source electrode pad 44. Specifically, interlayer insulating film 40 is disposed to cover at least gate electrode 32 and threshold adjustment layer 28 completely and not to cover part of source electrode 34. For example, interlayer insulating film 40 contains a silicon oxide film or a silicon nitride film as the main component. The thickness of interlayer insulating film 40 is larger than that of gate electrode 32, for example, although it is not particularly limited.

Gate electrode pad 42 is electrically connected to gate electrode 32. Gate electrode pad 42 is connected to a power supply for controlling gate electrode 32 or a drive circuit, outside semiconductor device 1. Gate electrode pad 42 is formed using a conductive material such as a metal.

Source electrode pad 44 is electrically connected to source electrode 34. Source electrode pad 44 is electrically connected to a power supply for supplying a source potential to source electrode 34 or a drive circuit, outside semiconductor device 1. Source electrode pad 44 is formed using a conductive material such as a metal.

As illustrated in FIG. 2, source electrode pad 44 is disposed apart from gate electrode pad 42 to avoid contact with gate electrode pad 42. In the planar view, source electrode pad 44 is disposed to cover substantially all the region of semiconductor device 1 excluding gate electrode pad 42, and is in contact with a plurality of source electrodes 34 arranged like islands.

### [Planar Layout]

Subsequently, the planar layout of semiconductor device 1 according to the present embodiment will be described with reference to FIG. 2.

The planar layout of semiconductor device 1 illustrated in FIG. 2 can be referred as a finger-type layout in which a plurality of source electrodes 34 are arranged in a comb shape. In (b) of FIG. 2, illustration of source electrode pad 44 is omitted.

Specifically, semiconductor device 1 includes a plurality of source electrodes 34 each having a shape elongated in the y-axis direction. The plurality of source electrodes 34 are arranged in the x-axis direction and the y-axis direction. The number of source electrodes arranged in the x-axis direction and the number of those arranged in the y-axis direction are not particularly limited. For example, one source electrode 34 may be disposed in the y-axis direction, that is, a plurality of source electrodes 34 need not to be arranged in the y-axis direction. Although not illustrated in FIG. 2, a plurality of source openings 30 are formed one-to-one corresponding to a plurality of source electrodes 34.

In the present embodiment, the longitudinal direction of source electrode 34 is the a-axis direction of GaN. Thereby, most of lateral surface 20b of gate opening 20 and lateral surface 30b of source opening 30 can be directed in the m-axis direction. As a result, facets of GaN crystals are not substantially generated in lateral surfaces 20b and 30b, and thus a favorable electrode contact and a low channel resistance can be implemented.

The longitudinal direction of source electrode 34 is not particularly limited. For example, the longitudinal direction of source electrode 34 may be the m-axis direction of GaN. In this case, the semiconductor layers formed on substrate 10 by crystal growth can have surfaces with favorable flatness. This leads to increased stability in processes such as light exposure, which can provide semiconductor device 1 with high quality and improve the yield.

As illustrated in FIG. 1, gate electrode 32 and threshold adjustment layer 28 are arranged between adjacent source electrodes 34. Specifically, in the planar view, gate electrode 32 is one flat plate-like electrode with first through holes formed in positions corresponding to source electrodes 34, each source electrode 34 being exposed from the first through hole. In the planar view, threshold adjustment layer 28 is one flat plate-like layer with second through holes formed in positions corresponding to source electrodes 34, each source electrode 34 being exposed from the second through hole. The first through holes and the second through holes are formed one-to-one corresponding to the plurality of source electrodes 34. Part of threshold adjustment layer 28 and the second through hole are exposed from the first through hole formed in gate electrode 32. Specifically, an edge portion of the second through hole, which is part of threshold adjustment layer 28, is exposed from the first through hole to surround source electrode 34. The shape of this edge portion in the planar view is a shape equivalent to the shape of gate opening 20 in the planar view, and is a ring shape of a numeric character “0” elongated in the longitudinal direction. In this specification, the ring shape may be referred to as zero pattern in some cases.

Semiconductor device 1 includes a plurality of gate openings 20. The plurality of gate openings 20 are arranged in the x-axis direction. The plurality of gate openings 20 each have a zero-patterned shape in the planar view. In the planar view, one source electrode 34 or a plurality of source electrodes 34 aligned in the y-axis direction are arranged on the inner circumference side of the ring of gate opening 20. One source electrode 34 or a plurality of source electrodes 34 aligned in the y-axis direction are arranged between adjacent gate openings 20.

As illustrated in FIG. 2, in the planar view, gate opening 20 includes two straight line portions 21a and 21b and two connection portions 21c and 21d.

Two straight line portions 21a and 21b are portions extending along the y-axis direction to sandwich source electrode 34. In the present embodiment, two straight line portions 21a and 21b each continuously extend across a plurality of source electrodes 34 aligned along the y-axis direction.

Connection portion 21c is one example of the first connection portion, and is a portion of an arch shape that connects first ends of two straight line portions 21a and 21b on the positive side of the y-axis direction. Connection portion 21d is one example of the second connection portion, and is a portion of an arch shape that connects second ends of two straight line portions 21a and 21b on the negative side of the y-axis direction.

Here, “arch shape” means that one of the positive side and the negative side of the y-axis direction includes a projecting shape. For example, connection portion 21c has a curve shape smoothly curved with a substantially uniform width. Specifically, the outline of connection portion 21c includes a half arc on the inner circumference side and on the outer circumference side.

By connecting the first ends of two straight line portions 21a and 21b into an arch shape, connection portion 21c can have a reduced curvature, compared to the case where the first ends of these are separately terminated with a half arc. Thereby, generation of growth singular points during regrowth can be effectively suppressed.

Connection portion 21d has an inverted shape of connection portion 21c. A modification applicable to connection portion 21c can also be applied to connection portion 21d. Connection portion 21d may have a shape different from that of connection portion 21c.

For example, the outline of connection portion 21c may be in an elliptical arc or a quadratic functional shape. The outline of connection portion 21c need not to be a curve. For example, the outline of connection portion 21c may be a broken line projecting to the positive side of the y-axis. Among a plurality of line segments forming the broken line, the angle formed by adjacent line segments is more than 90°. For example, vertices of the broken line may be arranged to be located on a virtual arc or elliptical arc. Use of such a broken line can enhance the precision of patterning when connection portion 21c is formed. The outline of connection portion 21c may be formed with a combination of straight lines (line segments) and curves.

As illustrated in FIG. 2, in semiconductor device 1, two source electrodes 34 aligned in the y-axis direction are arranged on the inner circumference side of gate opening 20 with a zero-patterned shape. Moreover, two source electrodes 34 aligned in the y-axis direction are arranged in a space between adjacent gate openings 20 in the x-axis direction.

In the present embodiment, in the planar view, gate electrode 32 overlaps with straight line portions 21a and 21b of gate opening 20. On the other hand, in the planar view, gate electrode 32 does not overlap with any of connection portions 21c and 21d of gate opening 20. Thereby, gate electrode 32 can be disposed not to overlap with anomaly growth regions 23a and 23b, which may be generated in regrowth layer 22 after formation of gate opening 20, in the planar view.

### [Anomaly Growth Region]

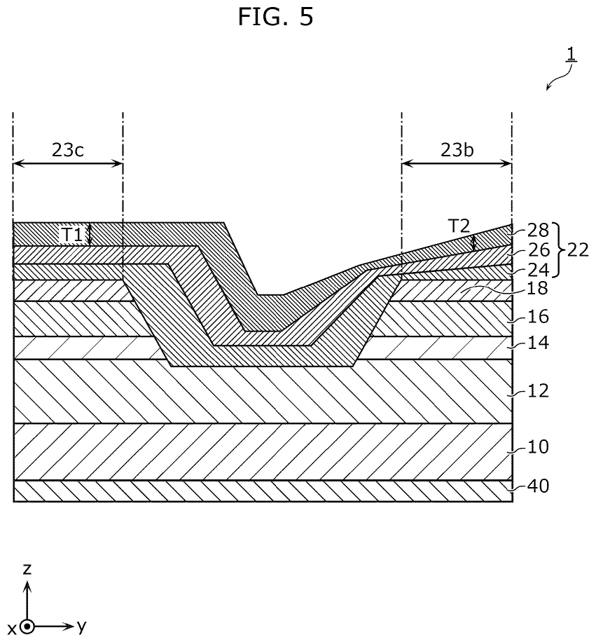

Subsequently, anomaly growth regions will be described with reference to FIGS. 4 and 5. FIGS. 4 and 5 are a plan view and a cross-sectional view schematically illustrating anomaly growth regions 23a and 23b of regrowth layer 22, respectively. FIG. 5 illustrates a cross-section taken along line V-V in FIG. 4.

As described above, after the formation of gate opening 20, regrowth layer 22 is formed by crystal growth to cover gate opening 20. At this time, in regrowth layer 22, anomaly growth attributed to the off-angle of the upper surface of substrate 10 is generated. Specifically, anomaly growth regions 23a and 23b shed along the off-angle direction of GaN crystals are formed. Anomaly growth more remarkably occurs as the off-angle becomes larger.

In anomaly growth regions 23a and 23b, the film thicknesses of the layers in regrowth layer 22 become smaller than the designed values. Specifically, as illustrated in FIG. 5, regrowth layer 22 includes normal region 23c and anomaly growth regions 23a and 23b outside gate opening 20 in the planar view. Normal region 23c is one example of the first region having a substantially uniform thickness. Anomaly growth regions 23a and 23b are one example of the second region, and have a thickness smaller than that of normal region 23c. In the present embodiment, anomaly growth regions 23a and 23b are regarded as a region having a film thickness that is 80% or less of the film thickness of the region without anomaly growth (specifically normal region 23c). For example, as illustrated in FIG. 5, film thickness T2 of threshold adjustment layer 28 in anomaly growth region 23b is smaller than film thickness T1 of threshold adjustment layer 28 in normal region 23c. The same is applied to electron transport layer 24 and electron supply layer 26.

To be noted, “outside gate opening 20 in the planar view” indicates a range outside lateral surface 20b of gate opening 20, in other words, a range not overlapping with either bottom surface 20a or lateral surface 20b in the planar view. Since the shape of gate opening 20 in the planar view is a zero-patterned shape, “outside gate opening 20” is present on the inner circumference side of the zero-patterned shape and the outer circumference side thereof.

In the planar view, when gate opening 20 is regarded as a reference, the ranges where anomaly growth regions 23a and 23b are formed are formed in the same direction. That is, anomaly growth of GaN crystals occurs to extend toward the off-direction from a position of the outline of gate opening 20 located in the off-direction (specifically, the positive side of the y-axis direction). The off-direction is the direction in which the crystal surface is inclined downward. In the present embodiment, the off-direction substantially matches with the longitudinal direction of source electrode 34, that is, the y-axis direction. Specifically, the angle formed by the off-direction and the y-axis direction is within ±10°. When the off-direction substantially matches with the y-axis direction, formation of the anomaly growth region within an active region can be suppressed, and thus, the properties of the device can be enhanced. For this reason, a smaller angle formed by the off-direction and the y-axis direction can more significantly enhance the properties of the device. Thus, the angle may be within ±5°, or may be within ±2°.

In the present embodiment, as illustrated in FIG. 4, anomaly growth region 23a is an anomaly growth region that occurs on the outer circumference side of the zero-patterned shape. It is formed from the outer circumference side of the outline of connection portion 21c toward the positive side of the y-axis direction. Anomaly growth region 23b is an anomaly growth region that occurs on the inner circumference side of the zero-patterned shape. It is formed from the inner circumference side of the outline of connection portion 21d toward the positive side of the y-axis direction.

It is expected that the region having a film thickness reduced due to anomaly growth of crystals is not substantially present in a portion surrounding source electrode 34. This is because a reduction in film thickness of threshold adjustment layer 28 leads to a change in threshold voltage of the transistor. Specifically, the distance between gate opening 20 and source electrode 34 that is greater than a predetermined value is ensured in the longitudinal direction (y-axis direction) of source electrode 34.

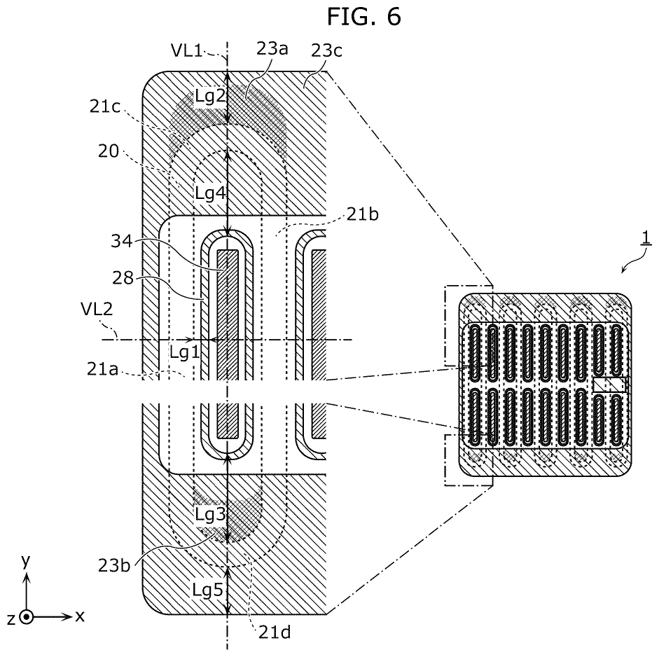

FIG. 6 is an enlarged plan view illustrating semiconductor device 1 according to the present embodiment. In FIG. 6, two virtual lines VL1 and VL2 are illustrated. Virtual line VL1 is one example of the first virtual straight line, and is a virtual straight line that passes through the center of source electrode 34 and is parallel to the y-axis direction in the planar view. Virtual line VL2 is one example of the second virtual straight line, and is a virtual straight line that passes through the center of source electrode 34 and is orthogonal to the y-axis direction (namely, parallel to the x-axis direction) in the planar view.

In semiconductor device 1, distances Lg2 and Lg3 illustrated in FIG. 6 are longer than distance Lg1. Distances Lg4 and Lg5 are longer than distance Lg1. Specifically, the following relations are satisfied.

$$Lg 1 > Lg 2 \qquad ( 1 )$$

$$Lg 1 > Lg 3 \qquad ( 2 )$$

$$Lg 1 > Lg 4 \qquad ( 3 )$$

$$Lg 1 > Lg 5 \qquad ( 4 )$$

Distance Lg1 is one example of the first distance, and is a distance on virtual line VL2. Distance Lg1 is the distance between the outline of straight line portion 21a on source electrode 34 side and the outline of threshold adjustment layer 28 on source electrode 34 side.

Distance Lg2 is one example of the second distance, and is a distance on virtual line VL1. Distance Lg2 is the distance between the outer edge outline of threshold adjustment layer 28 on connection portion 21c side (outline on the positive side of the y-axis direction) and the outline of connection portion 21c on a side opposite side of source electrode 34.

Distance Lg3 is one example of the third distance, and is a distance on virtual line VL1. Distance Lg3 is the distance between the outline of connection portion 21d on source electrode 34 side and the outline of threshold adjustment layer 28 on source electrode 34 side that is located between source electrode 34 and connection portion 21d.

Distance Lg4 is one example of the fourth distance, and is a distance on virtual line VL1. Distance Lg4 is the distance between the outline of connection portion 21c on source electrode 34 side and the outline of threshold adjustment layer 28 on source electrode 34 side that is located between source electrode 34 and connection portion 21c.

Distance Lg5 is one example of the fifth distance, and is a distance on virtual line VL1. Distance Lg5 is the distance between the outer edge outline of threshold adjustment layer 28 on connection portion 21d side (outline on the negative side of the y-axis direction) and the outline of connection portion 21d on a side opposite to source electrode 34.

As above, degradation of properties of the transistor can be suppressed by ensuring the distance between anomaly growth region 23a and source electrode 34 and that between anomaly growth region 23b and source electrode 34 that are longer than a predetermined value, in the ends in the longitudinal direction of source electrode 34.

### [Arrangement of Gate Electrode and Source Electrode]

In semiconductor device 1 according to the present embodiment, as illustrated in FIGS. 2 and 6, gate electrode 32 does not overlap with anomaly growth regions 23a and 23b in the planar view. The plurality of source electrodes 34 also do not overlap with anomaly growth regions 23a and 23b in the planar view.

In anomaly growth regions 23a and 23b, the film thicknesses of threshold adjustment layer 28, electron supply layer 26, and electron transport layer 24 can be smaller than the film thicknesses of those layers in normal region 23c. Depending on the growth conditions, the film thickness may be substantially zero. For this reason, when gate electrode 32 overlaps with anomaly growth region 23a or 23b, the leakage current flowing through gate electrode 32 increases.

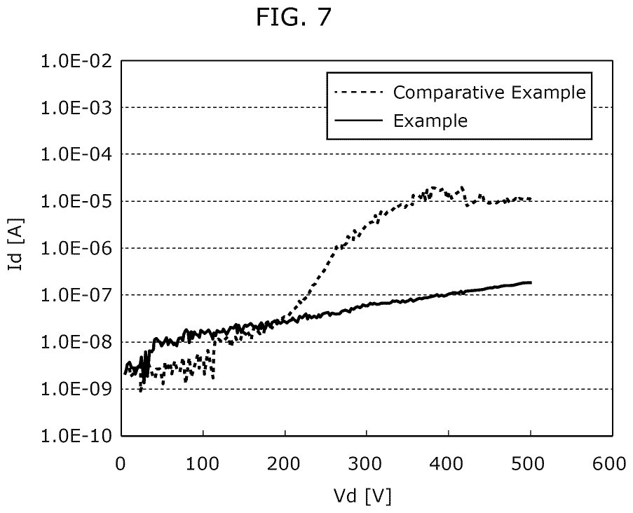

FIG. 7 is a graph illustrating off properties of semiconductor device 1 according to the present embodiment. In FIG. 7, the abscissa represents drain voltage Vd, and the ordinate represents drain current Id.

Example illustrated in FIG. 7 corresponds to semiconductor device 1 according to the present embodiment, and as illustrated in FIG. 2, gate electrode 32 does not overlap with anomaly growth regions 23a and 23b in the planar view. Comparative Example illustrated in FIG. 7 is a semiconductor device including a gate electrode disposed to overlap with anomaly growth regions 23a and 23b in the planar view. Example and Comparative Example have the same configuration excluding the gate electrode.

As illustrated in FIG. 7, in a range of drain voltage Vd of more than 200 V, large drain current Id flows in Comparative Example, while drain current Id can be suppressed in Example. In a range of the drain voltage of more than about 350 V, the effect of suppressing the leakage current that is about two digit higher than that in Comparative Example can be obtained.

The same is applied to a metal oxide semiconductor field effect transistor (MOSFET) where a gate insulating film is disposed as threshold adjustment layer 28. In other words, the leakage current can be reduced by arranging gate electrode 32 and source electrode 34 not to overlap with anomaly growth regions 23a and 23b in the planar view.

In semiconductor device 1, source electrode pad 44 is disposed above anomaly growth regions 23a and 23b with interlayer insulating film 40 interposed therebetween. Since interlayer insulating film 40 can suppress the leakage current, source electrode pad 44 may be disposed, or another wiring metal or the like may be disposed.

As above, semiconductor device 1 according to the present embodiment can suppress an increase in leakage current, and can implement high breakdown voltage properties.

### Embodiment 2

Subsequently, Embodiment 2 will be described.

In Embodiment 2, the shape of the gate opening in the planar view is different from that in Embodiment 1. Hereinafter, differences from Embodiment 1 will be mainly described, and description of the shared features will be omitted or simplified.

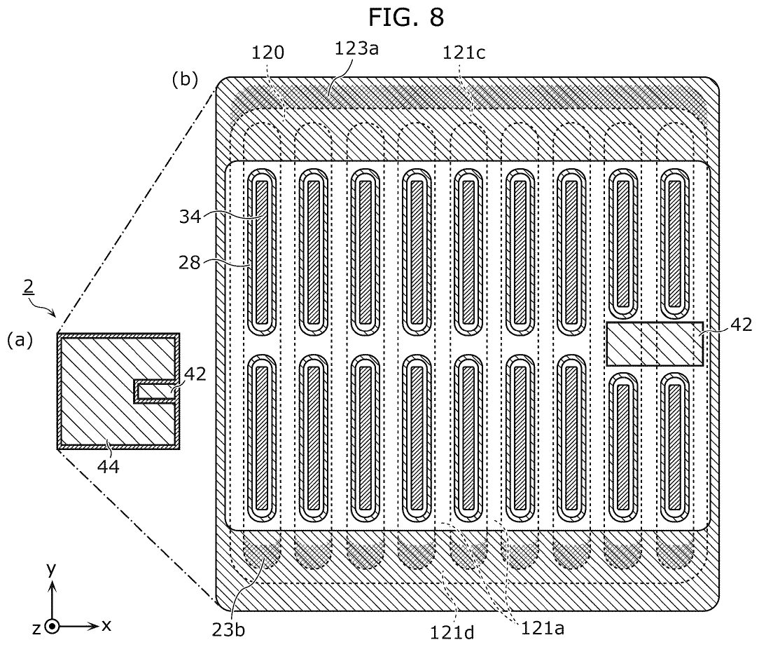

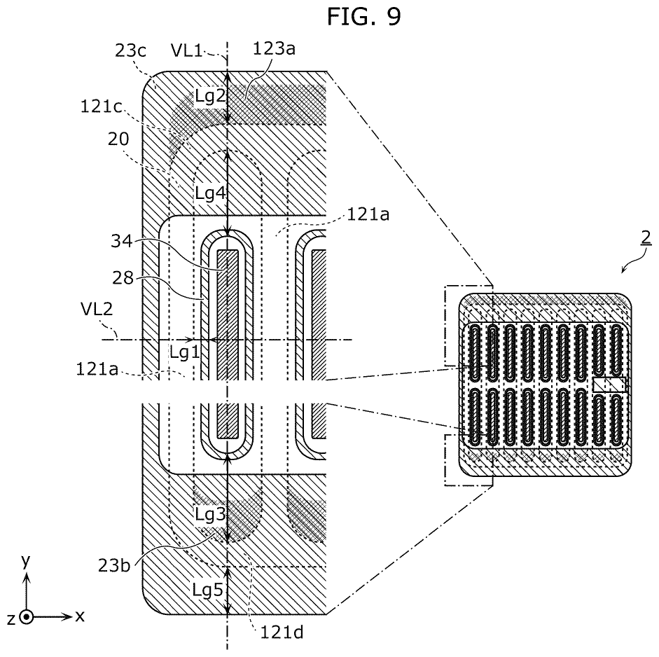

FIG. 8 is a plan view of semiconductor device 2 according to the present embodiment. FIG. 9 is an enlarged plan view illustrating semiconductor device 2 according to the present embodiment.

As illustrated in FIG. 8, unlike semiconductor device 1 according to Embodiment 1, semiconductor device 2 includes gate opening 120 instead of gate opening 20. The shape of gate opening 120 in the planar view is different from that of gate opening 20. Gate opening 120 is configured to have a structure in which a plurality of gate openings 20 illustrated in FIG. 2 are connected to each other in the x-axis direction on the positive and negative sides of the y-axis direction.

Specifically, gate opening 120 includes a plurality of straight line portion 121a and connection portions 121c and 121d in the planar view.

A plurality of straight line portions 121a are portions arranged between every adjacent source electrodes 34 in the x-axis direction. Each of the plurality of straight line portions 121a extends in the y-axis direction. In the present embodiment, each of the plurality of straight line portions 121a continuously extends across a plurality of source electrodes 34 aligned in the y-axis direction.

Connection portion 121c is one example of the first connection portion, and includes portions of an arch shape that are continuously arranged in the x-axis direction and each connect first ends of the plurality of straight line portions 121a on the positive side of the y-axis direction. Connection portion 121d is one example of the second connection portion, and includes portions of an arch shape that are continuously arranged in the x-axis direction and each connect second ends of the plurality of straight line portions 121a in the y-axis direction.

For example, the outline of connection portion 121c on the outer circumference side includes curved portions on both ends on the positive and negative sides in the x-axis direction, and the curved portions are connected with a straight line (line segment). The outline of connection portion 121c on the inner circumference side includes a plurality of half arcs, each of which connects adjacent straight line portions 121a. The specific shape of the outline of connection portion 121c is not particularly limited, and may be an elliptical arc, a broken line, or a combination of a line segment with a curve.

The shape of connection portion 121d is an inverted shape of that of connection portion 121c. Any modification applicable to connection portion 121c can also be applied to connection portion 121d. Connection portion 121d may have a shape different from that of connection portion 121c.

As in Embodiment 1, anomaly growth regions 123a and 23b are also formed in semiconductor device 2 according to the present embodiment. Anomaly growth regions 123a and 23b are formed to extend from the positive side of the outline of gate opening 120 in the y-axis direction to the positive side of the y-axis direction. In the present embodiment, the outline of connection portion 121c on the outer circumference side includes a line segment. Thus, anomaly growth region 123a is also formed to extend along the line segment in the x-axis direction.

In semiconductor device 2, both of distance Lg2 and distance Lg3 are longer than distance Lg1 as shown in FIG. 9. Both of distance Lg4 and distance Lg5 are longer than distance Lg1. In other words, the above-mentioned inequations (1) to (4) are satisfied. To be noted, distances Lg1, Lg2, Lg3, Lg4, and Lg5 shown in FIG. 9 are defined as in Embodiment 1.

Also in the present embodiment, gate electrode 32 and a plurality of source electrodes 34 do not overlap with anomaly growth regions 123a and 23b in the planar view. Thereby, semiconductor device 2 according to the present embodiment can suppress an increase in leakage current, and can implement high breakdown voltage properties.

In the present embodiment, an example in which all of straight line portions 121a included in gate opening 120 are connected by connection portion 121c or connection portion 121d, but any other configuration can be used. A plurality of gate openings each including straight line portions 121a connected may be arranged. Alternatively, connection portion 21c or 21d illustrated in Embodiment 1 may be disposed instead of connection portion 121c and connection portion 121d.

### Other Embodiments

As above, the semiconductor devices according to one or multiple aspects have been described d based on the embodiments, but the present disclosure is not limited to these embodiments. The present disclosure also covers embodiments obtained by subjecting the present embodiment to a variety of modifications conceived by persons skilled in the art and embodiments including any combination of components in different embodiments without departing from the gist of the present disclosure.

For example, an example in which a plurality of source electrodes have a shape elongated in one direction in the planar view has been described in the above-mentioned embodiments, but any other configuration can be used. For example, the plurality of source electrodes may have a regular hexagonal shape in the planar view. Moreover, the semiconductor device may include only one source electrode.

For example, the semiconductor layers may include a semiconductor different from the nitride semiconductor as the main component. For example, the semiconductor layers may include a compound semiconductor composed of GaAs or SiGe or a Si semiconductor as the main component. Even in this case, the leakage current can be reduced as in the semiconductor device including the nitride semiconductor according to the above-mentioned embodiments.

The semiconductor device is not limited to the vertical transistor. For example, the semiconductor device according to one aspect of the present disclosure may include a substrate, a first semiconductor layer of a first conductivity type disposed above the substrate, a second semiconductor layer of a second conductivity type disposed above the first semiconductor layer, the second conductivity having a polarity different from the first conductivity type, a third semiconductor layer disposed to cover a first opening that penetrates through the second semiconductor layer and reaches the first semiconductor layer, a first electrode disposed above the third semiconductor layer to cover the first opening, and a second electrode disposed below the substrate. In the semiconductor device according to this aspect, the third semiconductor layer includes a first region having a substantially uniform thickness and a second region having a thickness smaller than the thickness of the first region outside the first opening in the planar view of the substrate, in which the first electrode does not overlap with the second region in the planar view of the substrate. Even this configuration can suppress the leakage current via the second region, and can implement high breakdown voltage properties. Such a semiconductor device is a vertical diode, for example. Any modifications applicable to the above-mentioned transistor configurations and any combination thereof can also be applied to diodes unless contradiction occurs.

For example, the first conductivity type may be the p-type, and the second conductivity type may be the n-type.

Moreover, the above-mentioned embodiments can be subjected to a variety of modifications, replacements, additions, and omissions within the scope of CLAIMS or equivalents thereof.

### INDUSTRIAL APPLICABILITY

The present disclosure can be used in power devices used in power supply circuits for consumer products, for example.

1. A semiconductor device comprising:
a substrate;
a first semiconductor layer of a first conductivity type disposed above the substrate;
a second semiconductor layer of a second conductivity type disposed above the first semiconductor layer, the second conductivity having a polarity different from a polarity of the first conductivity type;
a third semiconductor layer disposed to cover a first opening that penetrates through the second semiconductor layer and reaches the first semiconductor layer;
a gate electrode disposed above the third semiconductor layer to cover the first opening;
a source electrode disposed apart from the gate electrode; and
a drain electrode disposed below the substrate,
wherein in a planar view of the substrate, outside the first opening, the third semiconductor layer includes:
a first region having a substantially uniform thickness; and
a second region having a thickness smaller than the thickness of the first region, and
in the planar view of the substrate, both of the gate electrode and the source electrode do not overlap with the second region.

2. The semiconductor device according to claim 1,
wherein the third semiconductor layer includes:
a fourth semiconductor layer including a channel region; and
a fifth semiconductor layer of the second conductivity type disposed between the fourth semiconductor layer and the gate electrode.

3. The semiconductor device according to claim 2,
wherein the source electrode has a shape elongated in a first direction in the planar view of the substrate, and
in the planar view of the substrate, the first opening includes:
two straight line portions that sandwich the source electrode and extend in the first direction;
a first connection portion of an arch shape that connects first ends of the two straight line portions in the first direction; and
a second connection portion of an arch shape that connects second ends of the two straight line portions on a side opposite to the first ends.

4. The semiconductor device according to claim 3,
wherein three or more source electrodes are included, each of which is the source electrode,
two or more first openings are aligned in a second direction orthogonal to the first direction, each of which is the first opening,
the three or more source electrodes are aligned in the second direction, and
each of the three or more source electrodes is disposed between adjacent first openings among the two or more first openings.

5. The semiconductor device according to claim 2,
wherein a plurality of source electrodes are included, each of which is the source electrode,
the plurality of source electrodes each have a shape elongated in a first direction in the planar view of the substrate,
in the planar view of the substrate, the plurality of source electrodes are aligned in a second direction orthogonal to the first direction, and
in the planar view of the substrate, the first opening includes:
a plurality of straight line portions, each of which is disposed between adjacent source electrodes in the second direction among the plurality of source electrodes and extends in the first direction;
a first connection portion including portions of an arch shape that are continuously arranged in the second direction and each connect first ends of the plurality of straight line portions in the first direction; and
a second connection portion including portions of an arch shape that are continuously arranged in the second direction and each connect second ends of the plurality of straight line portions on a side opposite to the first ends.

6. The semiconductor device according to claim 3,
wherein a plurality of source electrodes aligned in the first direction are included, each of which is the source electrode, and
each of a plurality of straight line portions continuously extends across the plurality of source electrodes aligned in the first direction.

7. The semiconductor device according to claim 3,
wherein when in the planar view of the substrate, a virtual straight line that passes through a center of the source electrode and is parallel to the first direction is defined as a first virtual straight line, and a virtual straight line that passes through a center of the source electrode and is orthogonal to the first direction is defined as a second virtual straight line,
(a) a distance on the second virtual straight line between an outline of one of the two straight line portions on a side of the source electrode and an outline of the fifth semiconductor layer on the side of the source electrode is defined as a first distance,
(b) a distance on the first virtual straight line between an outer edge outline of the fifth semiconductor layer on a side of the first connection portion and an outline of the first connection portion on a side opposite to the source electrode is defined as a second distance, and
(c) a distance on the first virtual straight line between an outline of the second connection portion on the side of the source electrode and an outline of the fifth semiconductor layer located between the source electrode and the second connection portion on the side of the source electrode is defined as a third distance,
both of the second distance and the third distance are longer than the first distance.

8. The semiconductor device according to claim 7,
wherein when in the planar view of the substrate,
(a) a distance on the first virtual straight line between an outline of the first connection portion on the side of the source electrode and an outline of the fifth semiconductor layer located between the source electrode and the first connection portion on the side of the source electrode is defined as a fourth distance, and
(b) a distance on the first virtual straight line between an outer edge outline of the fifth semiconductor layer on a side of the second connection portion and an outline of the second connection portion on a side opposite to the source electrode is defined as a fifth distance,
both of the fourth distance and the fifth distance are longer than the first distance.

9. The semiconductor device according to claim 1,
wherein a second opening that penetrates through the third semiconductor layer and reaches the second semiconductor layer is disposed in a position apart from the first opening in the planar view of the substrate, and
at least part of the source electrode is disposed inside the second opening.

10. The semiconductor device according to claim 1,
wherein the source electrode has a shape elongated in a first direction in the planar view of the substrate, and
the substrate includes an upper surface having an off-angle inclined with respect to the first direction.

11. The semiconductor device according to claim 8,
wherein the substrate contains gallium nitride, and
the first direction is an a-axis direction of gallium nitride.

12. The semiconductor device according to claim 10,
wherein the substrate contains gallium nitride, and
the first direction is an m-axis direction of gallium nitride.

13. The semiconductor device according to claim 1,
wherein the first semiconductor layer, the second semiconductor layer, and the third semiconductor layer all contain a nitride semiconductor as a main component.
